(19) United States
(12) Patent Application Publication
(10) Pub. No.: US 2005/0191807 A1
(43) Pub. Date: Sep. 1, 2005

(54) Method for forming shallow trench in deep trench structure

(75) Inventor: Sweehan J.H. Yang, Tainan City (TW)

Correspondence Address: BACON & THOMAS, PLLC, 625 SLATERS LANE, FOURTH FLOOR, ALEXANDRIA, VA, 22314, US

(73) Assignee: Nanya Technology Corporation, Taoyuan (TW)

(21) Appl. No.: 10/785,991

(22) Filed: Feb. 26, 2004

(51) Int. Cl. H01L 21/8242; H01L 21/20; H01L 21/76

(52) U.S. Cl. 438/248; 438/243

(57) ABSTRACT

Disclosed is a method for forming a shallow trench in a deep trench structure. The method of the present invention comprises steps of forming a liner layer on the deep trench structure; forming an amorphous silicon layer on the liner layer; implanting selected ions to a region of the amorphous silicon layer at a part of the deep trench; oxidizing the amorphous silicon layer to form an oxide layer, wherein the thickness of a portion of the oxide layer formed at the region of the amorphous silicon layer implanted with the selected ions is different from the thickness of a portion of the oxide layer formed at the region of the amorphous silicon layer not implanted with the selected ions; partially removing the oxide layer so that the thin portion of the oxide layer is removed and the thick portion of the oxide layer partially remains as a residual oxide layer; removing the portion of the liner layer not covered by the oxide layer to expose the poly-silicon therebelow; and etching the exposed poly-silicon to form a shallow trench.

### BACKGROUND OF THE INVENTION

1. Field of the Invention

The present invention relates to a semiconductor device process, more specifically, to a method for forming a shallow trench in a deep trench structure.

2. Description of the Prior Art

In 90 nm semiconductor process, it is necessary to form a shallow trench in a deep trench structure filled with poly-silicon for subsequent process.

FIGS. 1a to 1d illustrate the respective steps of a prior art method for forming a shallow trench in a deep trench structure. For simplicity, only the upper portion of the deep trench structure is shown. According to a general forming process of a deep trench, a pad oxide layer and a pad nitride layer are formed on a silicon substrate to constitute an intermediate structure. Then, a deep trench is formed in the intermediate structure, and the deep trench is filled with poly-silicon or the like. In the drawings, reference number 10 indicates a silicon substrate, 11 indicates a collar oxide layer, 12 indicates the upper most poly-silicon filled into the deep trench, 13 indicates a pad oxide layer, and 14 indicates a pad nitride layer.

After the completion of the deep trench structure, a thin liner layer 15 is formed on the entire structure. The liner layer 15 is preferably a nitride layer, generally being Si₃N₄. Then, a thin amorphous silicon layer 16 is formed on the liner layer 15, as shown in FIG. 1a.

Subsequently, tilt implantation of BF₂⁺ ions is implemented, that is, BF₂⁺ ions are forced to inclinedly strike the amorphous silicon layer 16 at a selected angle so as to be implanted into the amorphous silicon layer 16. Since BF₂⁺ ions are implanted by tilt implantation, a corner and a side of the amorphous silicon layer 16 in the recess of the deep trench structure are not implanted. When etching process is performed, the portion of the amorphous silicon layer 16 not implanted with BF₂⁺ ions is removed, while the portions of the amorphous silicon layer 16 implanted with BF₂⁺ ions remain, as shown in FIG. 1b. As shown, the portion of the liner layer 15 under the removed portion of the amorphous silicon layer 16 is exposed.

The exposed portion of the liner layer 15 is removed by wet etch, a shown in FIG. 1c.

With reference to FIG. 1d, the left liner layer 15 is used as a hard mask, and the poly-silicon 12 is dug to form a shallow trench by dry etch. Amorphous silicon layer 16 is also removed in this step. Then the residual liner layer 15 is removed.

However, there are some problems existing in prior art. In the step shown in FIG. 1c, when the liner layer 15, of which the material is nitride, is etched by wet etch to form an opening, the undercut phenomenon often occurs. Being confined to the dimension of the deep trench, the thickness of the liner layer 15 is limited. In the step of forming the shallow trench in the poly-silicon 12 by dry etch, the liner layer 15 made of nitride is not sufficient to be a good hard mask when etching the poly-silicon, since the etching selectivity for nitride to silicon is only about 30:1. Accordingly, the profile of the formed shallow trench is deformed and fails to meet the expectation, as shown in FIG. 1d.

Therefore, there is a need for a solution to overcome the problems stated above. The present invention satisfies such a need.

### SUMMARY OF THE INVENTION

An objective of the present invention is to provide a method for forming a shallow trench in a deep trench structure, by which the shallow trench is formed to have good profile.

According to an aspect of the present invention, in a method for forming a shallow trench in a deep trench structure, the deep trench structure comprises at least a substrate, a pad oxide layer and a pad nitride layer formed on the substrate. A deep trench is formed in the substrate having the pad oxide layer and the pad nitride layer formed thereon. The deep trench is filled with at least poly-silicon. The method comprises steps of forming a liner layer on the deep trench structure; forming an amorphous silicon layer on the liner layer; angled implanting selected ions to a region of the amorphous silicon layer at a part of the deep trench; oxidizing the amorphous silicon layer to form an oxide layer, wherein the thickness of a portion of the oxide layer formed at the region of the amorphous silicon layer implanted with the selected ions is different from the thickness of a portion of the oxide layer formed at the region of the amorphous silicon layer not implanted with the selected ions; partially removing the oxide layer so that the thin portion of the oxide layer is removed and the thick portion of the oxide layer partially remains as a residual hard mask oxide layer; removing the portion of the liner layer not covered by the oxide layer to expose the poly-silicon therebelow; and etching the exposed poly-silicon to form a shallow trench.

According to another aspect of the present invention, in the method for forming a shallow trench in a deep trench structure, the ions are selected so that the portion of the formed oxide layer is thin at the region implanted with the ions and the portion of the oxide layer is thick at the region not implanted with the ions.

According to a further aspect of the present invention, in the method for forming a shallow trench in a deep trench structure, the selected ions are N₂⁺ ions.

According to still a further aspect of the present invention, in the method of forming a shallow trench in a deep trench structure, the selected ions are implanted by ion tilt implantation.

### BRIEF DESCRIPTION OF THE DRAWINGS

The following drawings are only for illustrating the mutual relationships between the respective portions and are not drawn according to practical dimensions and ratios. In addition, the like reference numbers indicate the similar elements.

FIGS. 1a to 1d illustrates the respective steps of a method for forming a shallow trench in a deep trench structure in prior art; and

FIGS. 2a to 2f illustrates the respective steps of a method for forming a shallow trench in a deep trench structure in accordance with the present invention.

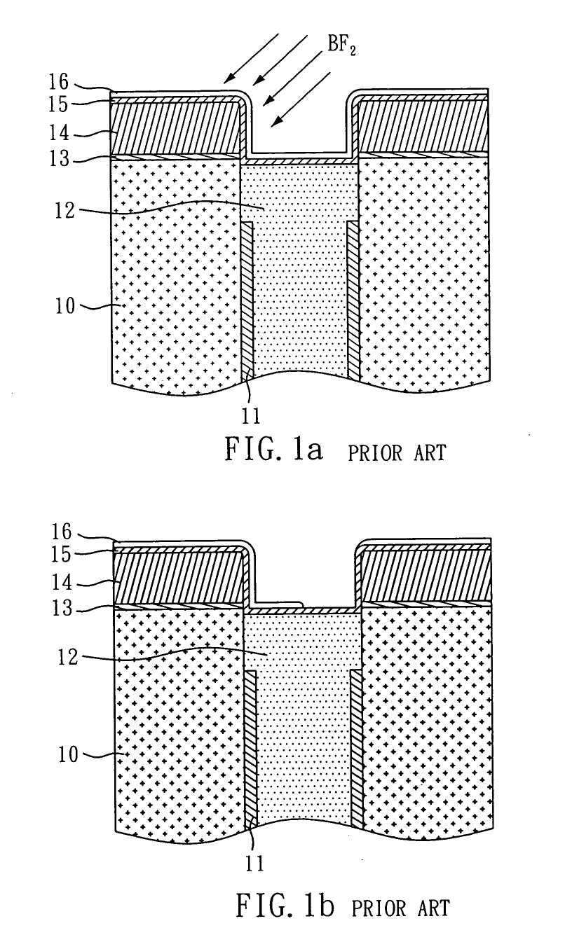

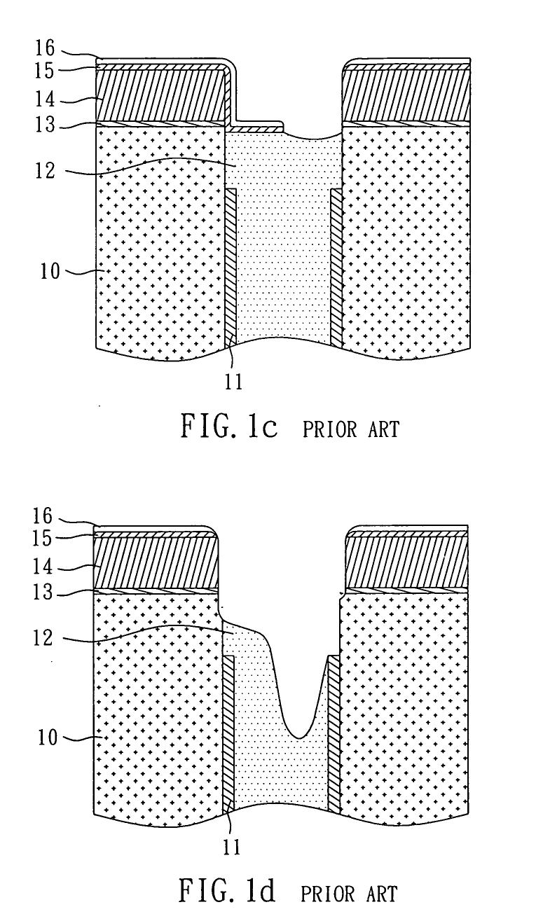

### DETAILED DESCRIPTION OF THE PREFERRED EMBODIMENT

An embodiment of the present invention will be described in detail with reference to the accompanying drawings.

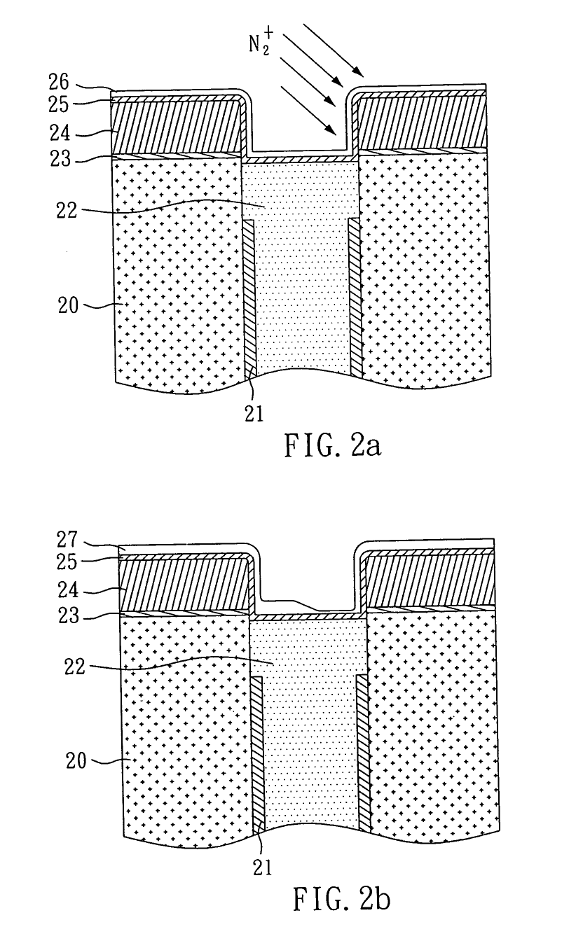

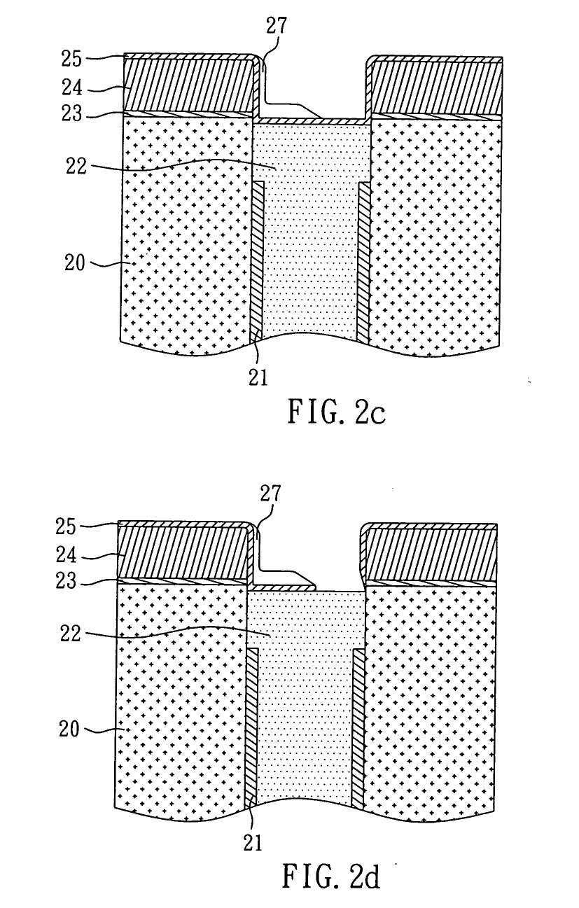

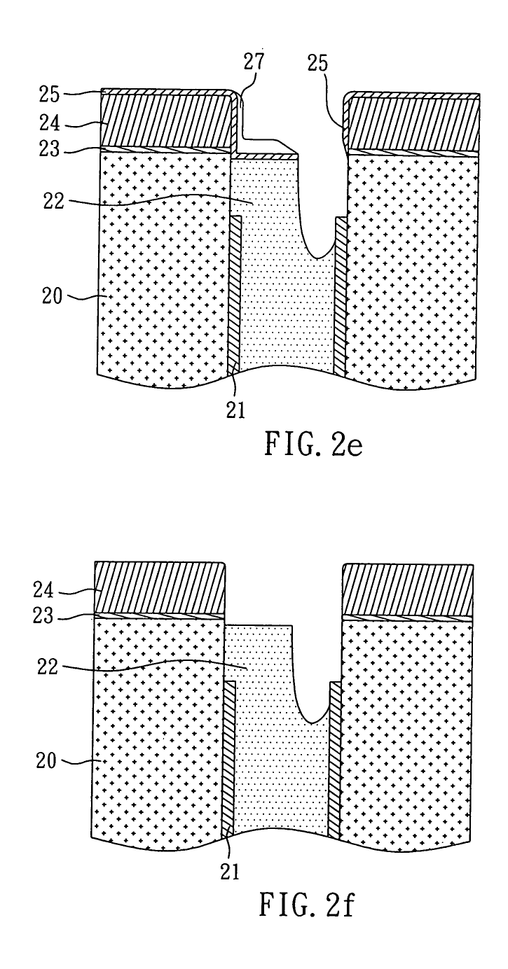

FIGS. 2a to 2f illustrates the respective steps of a method for forming a shallow trench in a deep trench structure in accordance with the present invention. For the sake of simplicity, only the upper portion of the deep trench structure is shown. In the drawings, reference number 20 indicates a silicon substrate, 21 indicates a collar oxide layer, 22 indicates the upper most poly-silicon filled into the deep trench, 23 indicates a pad oxide layer, and 24 is a pad nitride layer.

With reference to FIG. 2a, after the deep trench structure is completed, a thin liner layer 25 is formed on the structure. The liner layer 25 is preferably a nitride layer, such as Si3N4. Then, a thin amorphous silicon layer 26 is formed on the liner layer 25, similar to prior art. Subsequently, tilt implantation of N₂⁺ ions is performed, that is, N₂⁺ ions are forced to inclinedly strike on the amorphous silicon layer 26 so as to be implanted thereinto. Since N₂⁺ ions are implanted by an oblique angle, a corner and a side in the recess of the deep trench portion will not be implanted with the ions.

Next, the uppermost portion of the amorphous silicon layer 26 is oxidized by thermal oxidation or other proper methods to from an oxide layer 27, which contains silicon oxide, e.g. SiO₂. Since the amorphous silicon layer 26 is partially implanted with N₂⁺ ions, different regions of the formed oxide layer 27 have different thickness. At the region implanted with N₂⁺ ions, the formed oxide has a small thickness, while at the region not implanted with N₂⁺ ions, the formed oxide has a larger thickness, as shown in FIG. 2b. Although N₂⁺ ions are used in the present embodiment, any ions, which can make the thickness of the formed oxide different, can also be used.

Then, the oxide layer 27 is partially removed by a proper etching process, wherein the thin portion is completely removed, while the thick portion partially remained as a residual hard mask layer, as shown in FIG. 2c.

The left portion of the oxide layer 27 is used as etching hard mask. Using the hard mask, the portion of the liner layer 25 not covered with the hard mask, that is, the left oxide layer 27, is removed to expose a portion of the poly-silicon 22 by dry etching or other proper methods, as shown in FIG. 2d. Generally, due to the direction, the portion of the liner layer 25 at the side of the recess of the deep trench structure remains during etching. The left liner layer can function as protection.

Again, the left portion of the oxide layer 27 is used as hard mask. Using the hard mask, the exposed poly-silicon 22 is etched by dry etching or other proper processes to form a shallow trench, as shown in FIG. 2e.

Finally, the residual oxide layer 27 and liner layer 25 are removed, as shown in FIG. 2f.

In accordance with the present embodiment, the etching selectivity ratio for the material (i.e. SiO₂) of the oxide layer 27 compared to poly-silicon is very high, approaching 1:80 to 1:200. Accordingly, the oxide layer 27 can function as a good hard mask for the subsequent etching process. By this manner, the profile of the formed shallow trench is good.

While the embodiment of the present invention is illustrated and described, various modifications and alterations can be made by persons skilled in this art. The embodiment of the present invention is therefore described in an illustrative but not restrictive sense. It is intended that the present invention may not be limited to the particular forms as illustrated, and that all modifications and alterations which maintain the spirit and realm of the present invention are within the scope as defined in the appended claims.

1. A method for forming a shallow trench in a deep trench structure, said deep trench structure including at least a substrate, a pad oxide layer and a pad nitride layer formed on said substrate, said substrate having the pad oxide layer and pad nitride layer formed thereon having a deep trench formed therein, said deep trench being filled with at least poly-silicon, said method comprising steps of:
forming a liner layer on said deep trench structure;
forming an amorphous silicon layer on said liner layer;
implanting selected ions into partial regions of said amorphous silicon layer;
oxidizing said amorphous silicon layer to form an oxide layer, the portion of the oxide layer formed from the region of the amorphous silicon layer implanted with said selected ions having a thickness different from that of the portion of the oxide layer formed from the region of the amorphous silicon layer not implanted with said selected ions;
partially removing said oxide layer to remove the thin portion of the oxide layer and partially remove the thick portion of the oxide layer to leave a residual layer;
removing the portion of the liner layer not covered by said oxide layer to expose the poly-silicon; and
etching the exposed poly-silicon to form a shallow trench.

2. The method as claimed in claim 1 further comprising a step of removing the residual oxide layer and liner layer after the shallow trench is formed.

3. The method as claimed in claim 1, wherein said ions are selected so that the portion of the oxide layer formed from the region of the amorphous silicon layer implanted with said selected ions has a thickness thinner than that of the portion of the oxide layer formed from the region of the amorphous silicon layer not implanted with said selected ions.

4. The method as claimed in claim 3, wherein the selected ions are N₂⁺ ions.

5. The method as claimed in claim 1, wherein said ions are implanted by tilt implantation.
